(19) United States
(12) Patent Application Publication
(10) Pub. No.: US 2007/0272156 A1
(43) Pub. Date: Nov. 29, 2007

(54) Linear evaporator for manufacturing organic light emitting device using numerous crucibles

(75) Inventor: Il-Ho Noh, Gyeonggi-do (KR)

Correspondence Address: Grant J. Scott;Myers Bigel Sibley & Sajovec, P.A., P. O. Box 37428, Raleigh, NC, 27627, US

(73) Assignee: Semes Co., Ltd.

(21) Appl. No.: 11/803,297

(22) Filed: May 14, 2007

(30) Foreign Application Priority Data
May 23, 2006 (KR) 10-2006-0046222

(51) Int. Cl. C23C 16/00

(52) U.S. Cl. 118/726

(57) ABSTRACT

Provided is a linear evaporator for manufacturing a thin film of an organic light emitting device using a plurality of crucibles. The evaporator includes: a housing formed in a long cylinder shape and having an open top surface; a crucible fixing unit covering the housing and having a plurality of holes therein; a plurality of crucibles inserted in the housing through the plurality of holes, each of the crucibles having an open top surface and containing depositing materials therein; and a plurality of heating units, each of which is connected to the outer wall of each of the crucibles for heating each of the crucibles. The plurality of crucibles are inserted in the housing such that the distances between a substrate and a position where the depositing materials evaporated from the crucibles radially expand are different from each other

### CROSS REFERENCE TO RELATED APPLICATION

This application claims priority from Korean Patent Application No. 10-2006-0046222 filed on May 23, 2006, the disclosure of which is incorporated herein by reference in its entirety.

### BACKGROUND OF THE INVENTION

1. Field of the Invention

The present invention relates to a linear evaporator for manufacturing a thin film of an organic light emitting device, and more particularly, to a linear evaporator for manufacturing a thin film of an organic light emitting device using a plurality of crucibles, which is capable of uniformly depositing on a large substrate organic materials evaporated from the plurality of crucibles.

2. Description of the Related Art

Organic light emitting devices can be manufactured by numerous methods. Generally known are a method of evaporating a low molecular material under a vacuum state, and a method of melting a high molecular material in a solvent and subjecting it to spin coating.

In the method of manufacturing a thin film under a high vacuum state, shadow masks having a predetermined shape of opening are aligned in front of a substrate and then an organic material is deposited on the substrate.

In the manufacturing method, an evaporator is used for evaporating an organic material. The organic material evaporator includes a crucible and a cover. The crucible has an open top surface and receives an organic material. The cover has a plurality of perforations therein, through which an organic material is evaporated or sublimed.

To improve overall manufacturing productivity, a large substrate is used. When a large substrate is used, a linear evaporator is used to produce a uniformly distributed thin film. Evaporated organic materials are deposited on the entire substrate by moving either the large substrate or the linear evaporator.

Normally, the outer part of the linear evaporator has a smaller overlapping portion of the evaporated gas than that of the center. As a result, the outer part has a uniformity significantly lower than that of the center. As an approach to prevent this uneven distribution problem, the evaporator can be designed such that the length of the evaporator is longer than that of the substrate. Such design, however, reduces overall efficiency of the evaporator.

FIG. 1 is a cross-sectional view showing a conventional linear evaporator for manufacturing a thin film of an organic light emitting device. FIG. 2 is a plan view of the cover 20 shown in FIG. 1. One of the proposed approaches thus far to resolve the uneven distribution problem was to adjust the distance between and the area of perforations 25 of the cover 20. That is, as shown in FIG. 2, the distances between the perforations 25 are designed to become smaller (d1>d2>d3) and the sizes of the perforations 25 are designed to become larger (S1<S2<S3) from the center of the cover 20 to the outer part thereof so that a larger amount of organic materials pass through the outer part.

The approach, however, has a disadvantage in that it is difficult to precisely control the distances between and the sizes of the perforations since the sizes of the perforations are only several hundreds of micrometers to several millimeters. Further, in the case where very minute perforations are involved, the approach has an additional problem that the organic materials can be harden due to thermal deformation of the cover, which in turn can clog the perforations.

The above information disclosed in this Background section is only for enhancement of understanding of the background of the invention and therefore it may contain information that does not form the prior art that is already known in this country to a person of ordinary skill in the art.

### SUMMARY OF THE INVENTION

The invention has been made to provide a linear evaporator that can solve the above-described problems associated with the prior art.

One object of the invention is to uniformly deposit organic materials on a large substrate by varying vertical lengths by which organic materials evaporated from crucibles radially expand.

Objects of the invention are not limited to this, and other objects of the invention will be apparently understood by those skilled in the art through the following description.

In one aspect, the present invention provides a linear evaporator for manufacturing a thin film of an organic light emitting device, the evaporator comprising: (a) a housing formed in a long cylinder shape and having an open top surface; (b) a plurality of crucibles having an open top surface and containing depositing materials therein to be inserted in the housing; and (c) heating units heating the crucibles. The plurality of crucibles are inserted in the housing such that the distances between a substrate and a position where the depositing materials evaporated from the crucibles radially expand are different from each other.

Preferably, the distances become smaller from the center of the housing to the outer side thereof.

In a preferred embodiment, the plurality of crucibles have the same height and are arranged in a line in the housing, and the depths of the plurality of crucibles inserted in the housing become smaller from the center of the housing to the outer side thereof.

In another preferred embodiment, the plurality of crucibles have different heights and are arranged in a line in the housing, the heights become greater from the center of the housing to the outer side thereof, and the plurality of crucibles are inserted in the housing in the same depth.

In still another preferred embodiment, linear evaporators of the present invention may further comprise a plurality of height control units. Each of the height control units may be formed on each of at least two crucibles selected from the plurality of crucibles. Preferably, the plurality of crucibles have the same height and are arranged in a line in the housing, the depths of the plurality of crucibles inserted in the housing are the same, and the heights of the plurality of height control units becomes greater from the center of the housing to the outer side thereof.

In yet another preferred embodiment, linear evaporators of the present invention may further comprise a crucible fixing unit covering the housing and having a plurality of holes that pass through the upper portions of the crucibles inserted in the housing and have protrusion supports, wherein protrusions are formed on the outer walls of the crucibles to fix the crucibles to the housing by fitting to the protrusion supports of the crucible fixing unit.

In a further preferred embodiment, the heating units may comprise a heating line formed around the outer wall of each of the plurality of crucibles so as to heat each of the plurality of crucibles from the bottom thereof to a predetermined height.

Suitably, the predetermined height is greater than the height of the depositing materials disposed in each of the plurality of crucibles.

Other aspects of the invention are discussed infra.

### BRIEF DESCRIPTION OF THE DRAWINGS

The above and other features and advantages of the invention will become more apparent by describing in detail preferred embodiments thereof with reference to the attached drawings, in which:

FIG. 1 is a cross-sectional view showing a conventional linear evaporator for manufacturing a thin film of an organic light emitting device;

FIG. 2 is a plan view of a cover of the crucible shown in FIG. 1;

FIG. 3 is a cross-sectional view showing a linear evaporator for manufacturing a thin film of an organic light emitting device using a plurality of crucibles according to a first embodiment of this invention;

FIG. 4 is a perspective view showing a crucible connected with heating lines according to an embodiment of this invention;

FIG. 5 is a cross-sectional view showing a linear evaporator for manufacturing a thin film of an organic light emitting device using a plurality of crucibles according to a second embodiment of this invention;

FIG. 6 is a cross-sectional view showing a linear evaporator for manufacturing a thin film of an organic light emitting device using a plurality of crucibles according to a third embodiment of this invention;

FIG. 7 is a view showing results of evaporation and deposition according to the distance between a substrate and a position where the depositing materials evaporated from the crucibles radially expand; and

FIG. 8 is a plan view showing a crucible fixing unit according to an embodiment of this invention.

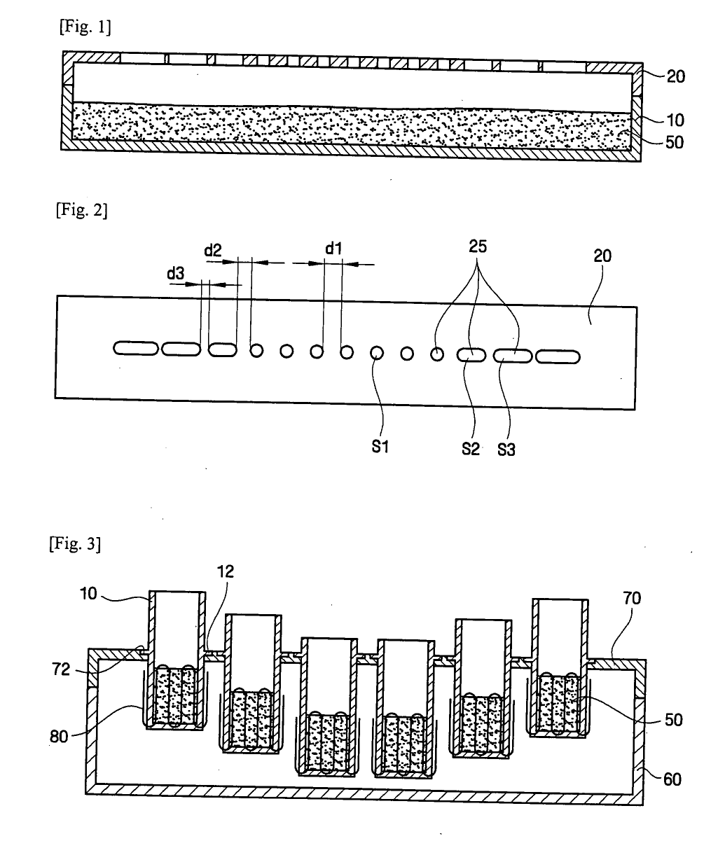

### DETAILED DESCRIPTION OF THE PREFERRED EMBODIMENTS

Reference will now be made in detail to the preferred embodiment of the present invention, examples of which are illustrated in the drawings attached hereinafter, wherein like reference numerals refer to like elements throughout. The embodiments are described below so as to explain the present invention by referring to the figures.

In one aspect, as discussed above, the present invention provides a linear evaporator for manufacturing a thin film of an organic light emitting device.

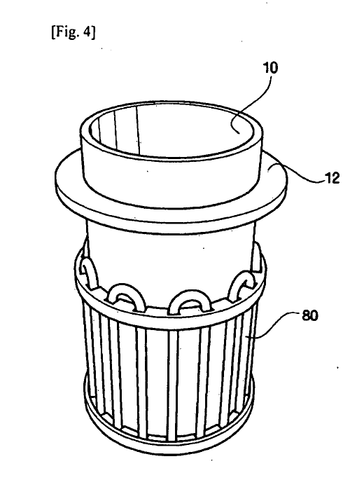

FIG. 3 is a cross-sectional view showing a linear evaporator for manufacturing a thin film of an organic light emitting device according to a first embodiment of this invention. The linear evaporator includes a plurality of crucibles 10 containing depositing materials, a housing 60 accommodating the crucibles 10, and a heating device that heats the crucibles to vaporize or sublimate the depositing materials.

The housing 60 is a case which has a open top surface and closed side and bottom surfaces. It defines a space therein to accommodate the plurality of crucibles 10. It is preferable that the width of the house 60 is longer than the width of a substrate in order to deposit organic materials on the entire substrate by moving the substrate or the linear evaporator.

Each of the crucibles 10 has a cylinder shape whose top surface is opened and side and bottom surfaces are closed. The depositing organic material 50 is contained in a space in the crucible 10.

FIG. 4 is a perspective view showing a crucible 10 connected with heating lines 80 according to an embodiment of this invention. The crucible 10 is preferably cylindrical. However, the crucible 10 may have various shapes such as rectangular, for example, as long as the top surface thereof is opened and an organic material 50 can be contained therein. On the outer wall of the crucible 10, a protrusion 12 is disposed. The protrusion 12 is configured to be able to fit a protrusion support 72 of a fixing member 70 (which will be described), thereby fixing the crucible 10 to the housing 60. The position of the protrusion 12 on the outer side of the crucible 10 can vary depending on the depth of the crucible 10 inserted in the housing. Preferably, the protrusion 12 is placed at a position higher than the position of a heating unit (which will be described in detail later). The heating unit is provided on the bottom portion of the outside of the crucible 10.

In a preferred embodiment, as shown in FIG. 3, the heights of the crucibles 10 are equal to each other, the crucibles are arranged in a line in the housing 60 and the heights of the crucibles 10 that are inserted in the housing are different from each other. Since the positions of protrusions 12 provided on the outer walls of the crucibles 10 can be different from each other, the protrusions 12 may be positioned on the protrusion supports 72 so that the crucibles 10 are inserted in the housing 60 with different depths. The depths of the crucibles 60 in the housing 60 are arranged so as to become smaller from the center to the outer side of the housing. Therefore, the heights of the evaporated organic materials 50 that are radially spread through the openings of the crucibles 10 (i.e., the distances between a substrate and a position where the depositing materials evaporated from the crucibles radially expand) are arranged to increase from the center to the outer side of the housing.

The heating unit is provided on the outer wall of the crucible 10 to heat the crucible 10 to vaporize the organic material 50 in the crucible 10. Preferably, the heating unit comprises a heating line 80, as shown in FIG. 4. Although it is not impossible to provide a heating line 80 in the entire height of the crucible 10, the height of a heating line 80 is, preferably, determined to be substantially the same as the height of the organic material 50 contained in the crucible 10. Since the same amount of organic material 50 is provided in each of the crucibles 10, the heights and the distances of the heating lines 80 are, preferably, arranged to be equal to each other in each crucible 10. With this arrangement, the heat can be uniformly transferred to each crucible 10. As a result, the amounts of evaporated organic materials 50 are equal in each crucible 10. It is noted that the heating unit may be implemented in various other ways that can heat a predetermined depth of the crucible 10.

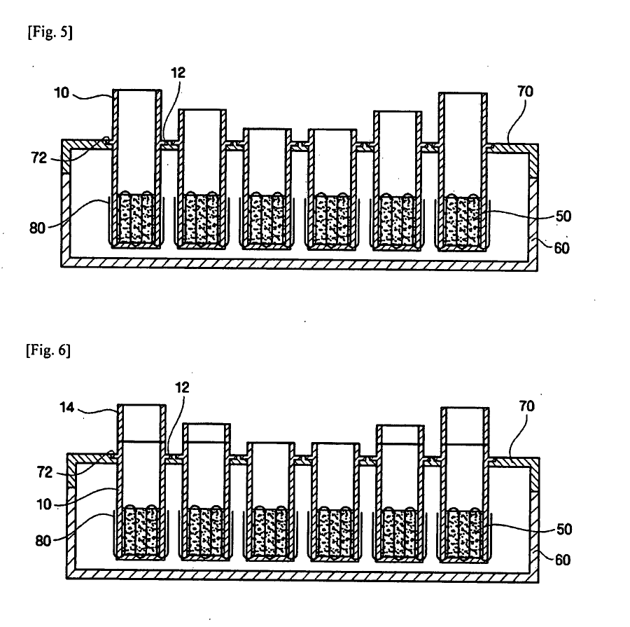

FIG. 5 is a cross-sectional view showing a linear evaporator for manufacturing a thin film of an organic light emitting device according to a second embodiment of this invention. The linear evaporator includes a plurality of crucibles 10 containing depositing materials, a housing 60 accommodating the crucibles 10, and a heating device that heats the crucibles to vaporize or sublimate the evaporating materials. Since these components are same as the first embodiment, the description will be omitted.

In a second preferred embodiment, however, the crucibles 10 have different heights, and are arranged in a line in the housing 60 having the same depth. Therefore, the heights of the crucibles 10 become greater from the center to the outer side of the housing. Therefore, the heights of the organic materials 50 that are radially evaporated through the openings of the crucibles 10 (i.e., the distances between a substrate and a position where the depositing materials evaporated from the crucibles radially expand) become greater from the center to the outer side.

FIG. 6 is a cross-sectional view showing a linear evaporator for manufacturing a thin film of an organic light emitting device according to a third embodiment of this invention. The linear evaporator includes numerous crucibles 10 containing depositing materials, a housing 60 accommodating the crucibles 10, and a heating device that heats the crucibles to vaporize or sublimate the evaporating materials. Since these components are same as the first embodiment, the description will be omitted.

In a third preferred embodiment, however, the heights of the crucibles are equal to each other and are arranged in a line in the housing 60, and the insertion depths in the housing are equal to each other. In this embodiment, height control units 14 are attached on at least two of the crucibles 10, and the heights of the height control units 14 becomes greater from the center to the outer side. Therefore, the heights of evaporated the organic materials 50 that are radially spread through the openings of the crucibles 10 (i.e., the distances between a substrate and a position where the depositing materials evaporated from the crucibles radially expand) become greater from the center to the outer side.

FIG. 7 is a view showing results of evaporation and deposition according to the distance between a substrate and a position where the depositing materials evaporated from the crucibles radially expand. Referring FIG. 7, the principle of uniformly depositing on a large substrate 100 according to an exemplary embodiment of this invention will be described. The left side of FIG. 7 shows a situation (I) where the distance between a substrate and a position where the depositing materials evaporated from the crucibles radially expand is small and the right side of FIG. 7 shows a situation (II) where the distance is large. The organic material evaporated in the crucible 10 radially spreads in a direction perpendicular to the substrate. Since the depositing material 50 radially spreads, the depositing material 50 reaches the substrate in a narrower area in the situation (I) compared to the situation (II). Since the depositing materials are evaporated in the same amount in both situations, the amount of the organic material in the unit area is larger in the situation (I) compared to the situation (II).

If the heights of the organic material 50 that radially spreads from the opening of the crucible 10 are equal to each other, overlapping amount of evaporated organic materials in the outer side of the housing is less than that in the center of the housing. As a result, when the evaporated organic material 50 is deposited on the substrate 100, the uniformity of the thin film at the outer side of the substrate is significantly lower than that in the center of the substrate 100.

In the preferred embodiments of the present invention, the heights of the openings of the crucibles 10 from which the organic materials spread are arranged to become greater from the center crucible to the crucible in the outer side. By this arrangement, although the overlapping amount of the evaporated organic material 50 in the crucible 10 in the outer side less than that in the center crucible 10, the amount of the organic material 50 deposited in the unit area is increased. As a result, it is possible to uniformly deposit the organic material 50 evaporated from all crucibles 10 on a large substrate 100.

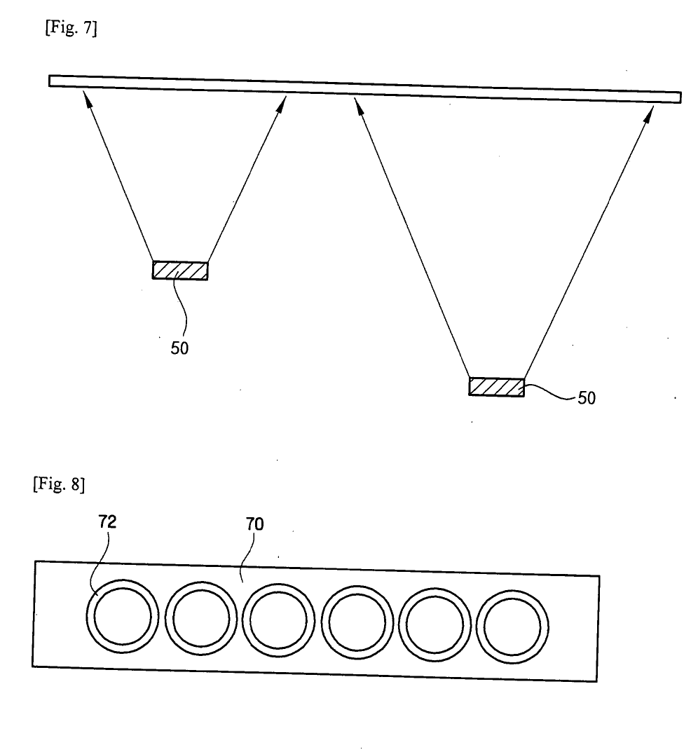

FIG. 8 is a plan view showing a crucible fixing unit according to an embodiment of this invention. The fixing unit includes a plurality of holes through which the crucibles 10 are inserted in the housing. As shown in FIG. 8, each of the holes has protrusion support 72 to fix the crucibles 10 by engagement with the protrusion 12. Even though it is not shown in the drawing, the crucible may be securely fixed by adding another coupling unit to the protrusion 12 and the protrusion support 72. The method of fixing the crucible with different insertion depths may be implemented by various methods other than the above method.

In another aspect, as discussed above, the present invention provides a method of manufacturing a thin film of an organic light emitting device in a linear evaporator.

Operation of the linear evaporator for manufacturing a thin film of an organic light emitting device according to the above embodiments of this invention will be described.

The crucible fixing unit 70 is disposed on the housing 60 to be fixed thereto. The crucibles 70 are inserted into the housing 60 so as to be fixed to the housing by fitting the protrusions 12 of the crucibles 10 to the protrusion supports 72 of the crucible fixing unit 70. The same amount of organic materials are contained in each crucible 10. The heating units are connected to the crucibles 10 in the same position and at the same distance to uniformly transfer heat to each 10. Therefore, equal amount of the organic material 50 is evaporated in each crucible 10 and moves toward the substrate. Since the heights of the evaporated organic materials 50 which are radially spread through openings of the crucibles (i.e., the distances between a substrate and a position where the depositing materials evaporated from the crucibles radially expand) become greater from the center of the housing 60 to the outer side, it is possible to uniformly deposit the organic materials on a large substrate.

As discussed above, according to the present invention, the organic material can be uniformly deposited without processing minute perforations.

The invention has been described in detail with reference to preferred embodiments thereof. However, it will be appreciated by those skilled in the art that changes may be made in these embodiments without departing from the principles and spirit of the invention, the scope of which is defined in the appended claims and their equivalents.

What is claimed is:

1. A linear evaporator for manufacturing a thin film of an organic light emitting device, the evaporator comprising:
(a) a housing formed in a long cylinder shape and having an open top surface;
(b) a plurality of crucibles having an open top surface and containing depositing materials therein to be inserted in the housing; and
(c) heating units, heating the crucibles,
wherein the plurality of crucibles are inserted in the housing such that the distances between a substrate and a position where the depositing materials evaporated from the crucibles radially expand are different from each other.

2. The linear evaporator of claim 1, wherein the distances become smaller from the center of the housing to the outer side thereof.

3. The linear evaporator of claim 2, wherein the plurality of crucibles have the same height and are arranged in a line in the housing, and the depths of the plurality of crucibles inserted in the housing become smaller from the center of the housing to the outer side thereof.

4. The linear evaporator of claim 2, wherein the plurality of crucibles have different heights and are arranged in a line in the housing, the heights become greater from the center of the housing to the outer side thereof, and the plurality of crucibles are inserted in the housing in the same depth.

5. The linear evaporator of claim 1, further comprising a plurality of height control units, each of which is formed on each of at least two crucibles selected from the plurality of crucibles, wherein the plurality of crucibles have the same height and are arranged in a line in the housing, the depths of the plurality of crucibles inserted in the housing are the same, and the heights of the plurality of height control units becomes greater from the center of the housing to the outer side thereof.

6. The linear evaporator of claim 1, further comprising a crucible fixing unit covering the housing and having a plurality of holes that pass through the upper portions of the crucibles inserted in the housing and have protrusion supports, wherein protrusions are formed on the outer walls of the crucibles to fix the crucibles to the housing by fitting to the protrusion supports of the crucible fixing unit.

7. The linear evaporator of claim 1, wherein the heating units comprise a heating line formed around the outer wall of each of the plurality of crucibles so as to heat each of the plurality of crucibles from the bottom thereof to a predetermined height.

8. The linear evaporator of claim 7, wherein the predetermined height is greater than the height of the depositing materials disposed in each of the plurality of crucibles.
